(19) United States
(12) Patent Application Publication
(10) Pub. No.: US 2022/0388279 A1
(43) Pub. Date: Dec. 8, 2022

(54) MULTILAYER PLATING FILM

(71) Applicant: C. Uyemura & Co., Ltd., Osaka (JP)

(72) Inventors: Katsuhisa TANABE, Osaka (JP); Tatsushi SOMEYA, Osaka (JP); Naoki NAKANO, Osaka (JP); Kazuki YAMAGUCHI, Osaka (JP)

(73) Assignee: C. Uyemura & Co., Ltd., Osaka (JP)

(21) Appl. No.: 17/828,522

(22) Filed: May 31, 2022

(30) Foreign Application Priority Data
Jun. 2, 2021 (JP) 2021-092865

(51) Int. Cl. B32B 15/01; C22C 19/03; C23C 18/42; C23C 18/50; H05K 1/09

(52) U.S. Cl. CPC B32B 15/018; C22C 19/03; C23C 18/42; C23C 18/50; H05K 1/09

(57) ABSTRACT

The present invention is to provide a plating film which can improve soldering bond reliability of solder bond against the accumulation of thermal history.

The present invention is a multilayer plating film comprising an electroless nickel-germanium alloy plating film; an electroless palladium plating film; and an electroless gold plating film in this order.

### CROSS-REFERENCE TO RELATED APPLICATIONS

This application is related to and claims priority under 35 U.S.C. 119 to Japanese patent application No. 2021-092865, filed on Jun. 2, 2021.

### TECHNICAL FIELD

The present invention relates to a multilayer plating film. In particular, the present invention relates to a multilayer plating film having property excellent in solder bonding reliability.

### BACKGROUND ART

Conventionally, when connecting circuit boards and electronic components, electroless nickel plating is applied as a barrier metal on conductor patterns such as copper patterns on the circuit board, followed by applying gold plating to improve connection reliability known as ENIG (Electroless Nickel Immersion Gold), or electroless nickel plating is applied as a barrier metal on conductor patterns, followed by applying electroless palladium on the nickel plating, and then applying gold plating to improve connection reliability known as ENEPIG (Electroless Nickel Electroless Palladium Immersion Gold).

In recent years, high densification and high functionality of electronic components mounted on printed circuit boards increase the load on solder bonds, however, solder bonds are required to operate without defects such as breakage or deterioration. For example, higher reliability is required for solder bonds in output control equipment such as traffic control equipment, engines, and other output control equipment.

As known techniques to improve the reliability of solder bonds, for example, Patent Document 1 discloses a technique to control the average nickel crystal size in a nickel plating layer to 2 μm or more.

Also, Patent Document 2 discloses a laminated film of an electroless nickel plating film, an electroless palladium plating film, and an immersion gold plating film, in which the electroless palladium plating film is composed of two layers of electroless palladium plating film having different purity of palladium.

### PRIOR ART DOCUMENT

### Patent Documents

Patent Document 1: Japanese Laid-open Patent Publication No. 2002-016100
Patent Document 2: Japanese Laid-open Patent Publication No. 2008-291348

### SUMMARY OF THE INVENTION

### Problems to be Solved by the Invention

It has been pointed out that thermal fatigue breakage by an accumulation of thermal history is one of the causes of solder bond failure. For example, solder bonds of electronic parts for vehicles are repeatedly subjected to large temperature differences by environmental temperature changes, radiation heat around an engine, or self-heating of electronic parts. This thermal history accumulates thermal fatigue in a solder bond, which may result in the breakage of the solder bond.

The present invention has accomplished to solve the above problem, it is an object of the present invention to provide a plating film which can improve soldering bond reliability (herein after may be called as bonding reliability) of solder bond against the accumulation of thermal history.

### Means to Solve the Problems

The present invention which solved above-described problem is as follows:

[1] A multilayer plating film comprising

an electroless nickel-germanium alloy plating film;

an electroless palladium plating film; and

an electroless gold plating film in this order.

[2] The multilayer plating film according to [1], wherein a content of germanium in the electroless nickel-germanium ally plating film is 0.01 to 25 mass %.

[3] A wiring substrate comprising:

a conductor surface of the wiring substrate is laminated by the electroless nickel-germanium alloy plating film, the electroless palladium plating film, and the electroless gold plating film according to [1] or [2] in this order.

### Effects of the Invention

The multilayer plating film of the present invention can improve solder bonding reliability of solder joint against the accumulation of thermal history.

### BRIEF DESCRIPTION OF THE DRAWINGS

FIG. 1 is a schematic view of the structure of the multilayer plating film of the present invention.

### MODE FOR CARRYING OUT THE INVENTION

ENEPIG films (electroless nickel plating film/electroless palladium plating film/immersion gold plating film) have excellent bonding reliability and wire bondability at room temperature but are prone to breakage due to the thermal history of the plating film in the solder bond area.

The present inventors have investigated the cause of breakage and found that repeated application of temperature variation with a large temperature difference to a solder bonding, for example, repeated application of stress caused by a difference in thermal expansion coefficient between an electronic part and a substrate, eventually causes the solder bonding to break. A detailed examination of the break points in the solder bonding revealed that the electroless nickel plating film was thermally degraded and prone to breakage. It was also found that the thermal history causes the growth of intermetallic compounds between a solder material and a plating film, which reduces the reliability of the bonding.

As a result of intensive research, the present inventors have reached the present invention by founding that a specific alloy component in an electroless nickel plating film can significantly improve bonding reliability.

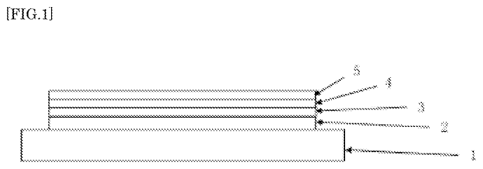

As shown in FIG. 1, a plating film of the present invention is a multilayer plating film having an electroless nickel-germanium alloy plating film 3, an electroless palladium plating film 4, and an electroless gold plating film 5 in this order. The multilayer plating film of the present invention has a synergistic effect of these three films to improve the bonding reliability.

The present invention also includes a wiring substrate in which the surface of the conductor 2 of the wiring substrate 1 is laminated by the electroless nickel-germanium alloy plating film 3, the electroless palladium plating film 4, and the electroless gold plating film 5 in this order. The multilayer plating film of the present invention is formed on at least part of a conductor surface, preferably on the conductor surface composing a solder bonding part. The multilayer plating film of the present invention may be formed on the whole surface of a conductor except a solder bonding part.

Each plating film composition is described below.

### Electroless Nickel-Germanium Alloy Plating Film

The electroless nickel-germanium alloy plating film of the present invention is an alloyed plating film of germanium and nickel. The germanium provides superior bonding reliability against thermal history compared with that of conventional electroless Ni—P plating films. Bonding reliability cannot be obtained with electroless nickel alloy plating films other than the electroless nickel-germanium alloy plating film, such electroless nickel alloy plating films include electroless Ni—Fe alloy plating films, electroless Ni—Cu alloy plating films, and electroless Ni—Sn alloy plating films as shown in the examples.

Germanium is essential for the electroless nickel-germanium alloy plating film to exhibit bonding reliability, and a higher germanium content is desirable for better bonding reliability. On the other hand, as the germanium content excessively increases, the nickel content decreases, resulting in changes in such as conductivity and adhesion, and decreases in bonding reliability.

The germanium content in the electroless nickel-germanium alloy plating film is preferably 0.01 mass % or more, more preferably 0.1 mass % or more, further preferably 1.0 mass % or more, and preferably less than 50 mass %, more preferably 30 mass % or less, further preferably 25 mass % or less, and even more preferably 20 mass % or less.

The remainder of the electroless nickel-germanium alloy plating film, excluding the above germanium content, is nickel and unavoidable impurities.

The composition of the electroless nickel-germanium alloy plating film is determined by an ICP emission spectrometer and adopt the measurement conditions of the examples.

One preferable embodiment, as the thickness of the electroless nickel-germanium ally plating film increases, bonding reliability increases. On the other hand, as the thickness of the electroless nickel-germanium ally plating film excessively increases, the effect of improved bonding reliability may be saturated and lose economical merit.

The thickness of the electroless nickel-germanium alloy plating film is preferably 0.01 μm or more, more preferably 1.0 μm or more, and preferably 100 μm or less, more preferably 10 μm or less.

### Third Component

The electroless nickel-germanium alloy plating film is preferably composed of nickel and germanium without containing an alloy component (third component) other than nickel and germanium.

The electroless nickel-germanium alloy plating film allows unavoidable impurities as a third component derived from raw materials such as a reducing agent. The unavoidable impurities derived from raw materials are preferably 15 mass % or less, more preferably 10 mass % or less, further preferably 5 mass % or less, and even more preferably 0 mass %.

An electroless nickel-germanium alloy plating film containing a third component may change film quality, easily causing thermal degradation above and easily forming intermetallic compounds, which decrease bonding reliability.

### Electroless Palladium Plating Film

The electroless palladium plating film is effective in preventing thermal diffusion of nickel and improving heat resistance. The layered structure of the electroless nickel-germanium alloy plating film, the electroless palladium plating film, and the electroless gold plating film, in order from the substrate side, improves the bonding reliability.

The electroless palladium plating film may contain alloy components other than palladium (herein after may be called as other alloy components). Other alloy components include such as phosphorus, boron, and germanium, and one or more of the other alloy components may be used in combination.

The content of other alloy components in the electroless palladium plating film (total amount in the case of two or more types are contained) is set to achieve the desired effect. However, excessively large content of other alloy components changes the film quality of the plating film and decreases the above effect. The content of other alloy components is preferably 10 mass % or less, more preferably 8 mass % or less, or 0 mass % (not included).

In the case of the electroless palladium plating film containing no other alloy components, the content of palladium is preferably 99.9 mass % or more and unavoidable impurities are allowed as the remaining portion, more preferably 100 mass %.

Excessively thin electroless palladium plating film may not be effective in improving bonding reliability and preventing the diffusion of nickel and other metals. Also, excessively thick electroless palladium plating film may deteriorate bonding reliability.

The thickness of the electroless palladium plating film is preferably 0.01 μm or more, more preferably 0.02 μm or more, and preferably 1.0 μm or less, more preferably 0.5 μm or less, further preferably 0.3 μm or less.

### Electroless Gold Plating Film

The electroless gold plating film is effective in improving solder wettability and heat resistance. The layered structure of the electroless nickel-germanium alloy plating film, the electroless palladium plating film, and the electroless gold plating film, in order from the substrate side, improves the bonding reliability.

An electroless gold plating film containing alloy components other than gold may change the film quality, decreasing the above effects such as bonding reliability. The content of gold in the electroless gold plating film is preferably 99.9 mass % or more and unavoidable impurities are allowed as the remainder, more preferably 100 mass %.

The thickness of the electroless gold plating film may be set according to the desired characteristics. For example, as the thickness of the electroless gold plating film increases, solder wettability improves.

The thickness of the electroless gold plating film is preferably 0.01 μm or more, more preferably 0.05 μm or more, and preferably 1.0 μm or less, more preferably 0.5 μm or less.

The electroless gold plating film can be either an immersion gold plating film or a reduction gold plating film. The electroless gold plating film is preferably an immersion gold plating film which allows the multilayer plating film of the present invention to be treated in the same way as a ENEPIG film.

The multilayer plating film consists of the layers of above three films, which are laminated in the order shown in FIG. 1. The present invention does not include any plating film other than the above plating film (other plating films) because the presence of other plating films reduces the bonding reliability.

The method for forming the multilayer plating film of the present invention is described below.

In the present invention, after applying pretreatment such as degreasing and activation, as necessary, to an object to be plated, an electroless nickel-germanium alloy plating film is formed on the pretreated object, followed by forming an electroless palladium plating film, and then forming an electroless gold plating film thereon.

The object to be plated is a metal material that constitutes a conductor, such as an electrode or wiring formed on the surface of a substrate. The metal material can be any material capable of forming electroless nickel-germanium alloy plating film, such metal material includes Al and Al-based alloys, Cu and Cu-based alloys, and various other known metal materials.

The substrates include various known insulating substrates such as resin substrates, ceramic substrates, glass substrates, and wafer substrates.

The pretreatment includes, but not limited to, cleaner treatment, acid cleaning, etching, pre-dip, and catalyst. Various known pretreatments may be performed as needed.

### Electroless Nickel-Germanium Alloy Plating Treatment

In the electroless nickel-germanium alloy plating process, the object to be plated is immersed in an electroless nickel-germanium alloy plating solution to form an electroless nickel-germanium alloy plating film. The immersion time is not limited, and the immersion time may be selected, such as from 10 seconds to 50 minutes, to obtain the desired thickness of the above desired electroless nickel-germanium alloy plating film. In the electroless nickel-germanium alloy plating treatment, the plating solution may be agitated or the object to be plated may be shaken as necessary.

### Electroless Nickel-Germanium Alloy Plating Solution

The electroless nickel-germanium alloy plating solution contains water-soluble nickel salt as a nickel source.

Water-soluble nickel salts include inorganic water-soluble nickel salts such as nickel sulfate, nickel bromide, nickel chloride, and nickel sulfamate; organic water-soluble nickel salts such as nickel carbonate and nickel acetate. Among them, preferable water-soluble nickel salt is nickel sulfate hexahydrate.

These water-soluble nickel salts can be used alone or in combination.

The concentration of above water-soluble nickel compound in electroless nickel-germanium alloy plating solution (single concentration when used alone, or total concentration when two or more kinds are used together) is preferably high concentration for improving deposition speed. However, as the concentration of water soluble nickel compound excessively increases, the deposition rate may become too fast or the plating solution stability may decrease.

The concentration of water-soluble nickel compound as nickel concentration (Ni equivalent) is preferably 0.1 g/L or more, more preferably 1.0 g/L or more, and preferably 100 g/L or less, more preferably 25 g/L or less.

Electroless nickel-germanium alloy plating solution contains water-soluble germanium compound as a germanium source. Water-soluble germanium compound includes such as germanium oxide, germanium chloride, germanium bromide, and germanium sulfide. Among them, preferable water-soluble germanium compound is germanium oxide.

These water-soluble germanium compound can be used alone or in combination.

The concentration of above water-soluble germanium compound in electroless nickel-germanium alloy plating solution (single concentration when used alone, or total concentration when two or more kinds are used together) is preferably high concentration for improving bonding reliability. On the other hand, as the concentration of water-soluble germanium compound excessively increases, the plating solution stability may decrease.

The concentration of the water-soluble germanium compound as germanium concentration (Ge equivalent) is preferably 0.01 g/L or more, more preferably 0.02 g/L or more, further preferably 0.1 g/L or more, even more preferably 1.0 g/L or more, and preferably 100 g/L or less, more preferably 25 g/L or less, further preferably 23 g/L or less, even more preferably 15 g/L or less.

### Reducing Agent

The reducing agent used in the present invention can be any known reducing agent used in electroless nickel plating solutions as long as the reducing agent has the ability to reduce and deposit nickel ion and germanium ion.

Examples of the reducing agent include hypophosphite; hypophosphites such as sodium hypophosphite, potassium hypophosphite, and ammonium hypophosphite; amine borane compounds such as dimethylamine borane and trimethylamine borane; borohydride compounds such as sodium borohydride and potassium borohydride; hydrazines. Hydrazines can be hydrazine; hydrazine hydrate such as hydrazine monohydrate; hydrazine salts such as hydrazine carbonate, hydrazine sulfate, hydrazine neutral sulfate, and hydrazine hydrochloride; organic derivatives of hydrazine such as pyrazoles, triazoles, and hydrazides; and others.

The above reducing agent can be used alone or in combination.

The concentration of the reducing agent in the electroless nickel-germanium alloy plating solution (single concentration when used alone, or total concentration when two or more reducing agents are used together) depends on the type of reducing agent, however, the concentration is preferably adjusted to provide sufficient reduction action. Although a high concentration of the reducing agent is desirable considering the plating deposition rate, an excessively high concentration of the reducing agent may decrease the stability of the plating solution.

The concentration of the reducing agent in the plating solution is preferably 0.5 g/L or more, more preferably 1.0 g/L or more, further preferably 10 g/L or more, and preferably 100 g/L or less, more preferably 50 g/L or less.

Reductant component such as phosphorus (P), for example, may be included in the electroless nickel-germanium alloy plating film derived from the reducing agent. In the present invention, the nickel-germanium alloy film provides bonding reliability, therefore, the film may contain phosphorus and other components derived from the reducing agent, which are acceptable as unavoidable impurities.

### Complexing Agent

The complexing agent used in the electroless nickel-germanium alloy plating solution of the present invention can be any known complexing agent used in electroless nickel plating solutions.

The complexing agent includes, for example, monocarboxylic acids such as acetic acid, formic acid, propionic acid, butyric acid, or their salts; dicarboxylic acids such as malonic acid, succinic acid, adipic acid, maleic acid, oxalic acid, fumaric acid, or their salts; oxycarboxylic acids such as malic acid, lactic acid, glycolic acid, gluconic acid, citric acid, tartaric acid, or their salts; and aminocarboxylic acids such as glycine, alanine, arginine, aspartic acid, glutamic acid, or their salts. Salts include, for example, alkali metal salts such as sodium, potassium, and lithium; alkaline earth metal salts such as calcium; and soluble salts such as ammonium salts.

The above complexing agent can be used alone or in combination.

The concentration of the complexing agent in the electroless nickel-germanium alloy plating solution (single concentration when used alone, or total concentration when two or more kinds are used together) is preferably high concentration for improving plating deposition speed. On the other hand, as the concentration of the complexing agent excessively increases, the effect of adding the complexing agent may be saturated.

The concentration of the complexing agent is preferably 5 g/L or more, more preferably 10 g/L or more, and preferably 200 g/L or less, more preferably 80 g/L or less.

The electroless nickel-germanium alloy plating solution may be mixed with known additives used for electroless nickel plating solutions as needed, in addition to the above mentioned components.

Additives include, for example, stabilizers, pH adjusters, and surfactants.

### Stabilizer

As the stabilizer, various known stabilizers having effective in stabilizing the plating solution can be used.

Stabilizers include, for example, lead compounds such as lead nitrate and lead acetate; cadmium compounds such as cadmium nitrate and cadmium acetate; thallium compounds such as thallium nitrate and thallium nitrate; antimony compounds such as antimony chloride and potassium antimonyl tartrate; chromium compounds such as chromium oxide and chromium sulfate; divalent or trivalent iron ion sources such as iron sulfate, iron chloride, iron sulfide, iron nitrate, iron oxide; iodine ion sources such as potassium iodide, iron iodide, nickel iodide, lithium iodide, sodium iodide. Among these stabilizers, a combination use of iron ion source and iodine ion source is preferred to inhibit decomposition of the plating solution and stabilizes the plating solution.

The stabilizers can be used alone or in combination.

The concentration of the stabilizer in the electroless nickel-germanium alloy plating solution is not limited and may be sufficient concentration to improve stability.

The concentration of the stabilizer (single concentration when used alone, or total concentration when two or more stabilizers are used together) is preferably 0.01 mg/L or more, more preferably 0.1 mg/L or more, and preferably 100 mg/L or less, more preferably 10 mg/L or less. Combination use of iron ion source and iodine ion source is preferably adjusted by the iron ion source to 0.1 to 100 mg/L and the iodine ion source to 10 to 4000 mg/L.

### pH Adjuster

As the pH adjuster, various known pH adjusters having an effect of adjusting the pH of the plating solution to a predetermined value can be used.

Examples of the pH adjuster include acids such as hydrochloric acid, sulfuric acid, and phosphoric acid; and alkalis such as sodium hydroxide, potassium hydroxide, and ammonia water.

As the pH of the electroless nickel-germanium alloy plating solution is excessively low, the deposition rate of nickel and germanium may decrease, resulting in poor deposition of the nickel-germanium alloy plated film, and defects such as pores may occur on the film surface. On the other hand, excessively high pH of the solution brings excessively fast deposition rate of nickel and germanium, resulted in difficulty in controlling film thickness.

The pH of the electroless nickel-germanium alloy plating solution is preferably 2.0 or higher, more preferably 4.0 or higher, and preferably 12.0 or low, more preferably 10.0 or low.

### Surfactant

As the surfactant, various known surfactants such as nonionic, anionic, cationic, and amphoteric surfactants can be used alone or in combination.

The concentration of the surfactant in the electroless nickel-germanium alloy plating solution is not limited and may be sufficient concentration to achieve the surfactant addition effect. The concentration of the surfactant (single concentration when used alone, or total concentration when two or more surfactants are used together) is preferably 0.01 mg/L or more, more preferably 0.1 mg/L or more, and preferably 100 mg/L or less, more preferably 10 mg/L or less.

### Temperature

The temperature of the electroless nickel-germanium alloy plating solution during its treatment is preferably in the range of 30° C. to 90° C. Excessively low temperature of the solution may decrease the precipitation rate. On the other hand, excessively high temperature of the solution may be excessively high deposition rate or increase water evaporation from the plating solution, resulting in fluctuations in the solution composition.

The liquid temperature of the electroless nickel-germanium alloy plating solution is preferably 30° C. or higher, more preferably 40° C. or higher, and preferably 90° C. or lower, more preferably 80° C. or lower.

### Electroless Palladium Plating Treatment

The electroless palladium plating film is formed on the surface of the electroless nickel-germanium alloy plating film. When the electroless palladium plating treatment is applied after the electroless nickel plating treatment, for example, conducting water cleaning treatment after forming the electroless nickel-germanium alloy plating film, and then conducting activation treatment using the activating composition of the present invention, followed by another water cleaning treatment if necessary. The electroless palladium plating film can be formed (laminated) on the surface of the electroless nickel-germanium alloy plating film by immersing an object to be plated with the electroless nickel-germanium alloy plating film in the electroless palladium plating solution.

The immersion time is not limited, and the immersion time may be selected such as 1 to 20 minutes to form a desired electroless palladium plating film with desired thickness.

### Electroless Palladium Plating Solution

A plating solution and a plating method used for the electroless palladium plating treatment can adopt the known electroless palladium plating solutions and electroless palladium plating methods used to form ENEPIG.

The electroless palladium plating solution is an aqueous solution containing palladium compound, reducing agent and complexing agent as essential components.

The electroless palladium plating solution contains water-soluble palladium compounds as a palladium source. Usable water-soluble palladium compound include such as palladium sulfate, palladium chloride, palladium acetate, dichlorodiethylenediamine palladium, and tetraammonium palladium dichloride.

These water-soluble palladium compound can be used alone or in combination.

The concentration of the water-soluble palladium compound in the electroless palladium plating solution (single concentration when used alone, or the total concentration when two or more compounds are used together) is preferably high concentration considering the above effects of the electroless palladium plating film. On the other hand, as the concentration of the palladium compound excessively increases, the stability of the plating solution may decrease.

The concentration of the water-soluble palladium compound as palladium (Pd) concentration is preferably 0.1 g/L or more, more preferably 0.5 g/L or more, and preferably 30 g/L or less, more preferably 10 g/L or less.

### Reducing Agent

The reducing agent used in the present invention can be any known reducing agent used in electroless palladium plating solutions as long as the reducing agent has the ability to reduce and deposit palladium ion.

The reducing agent is at least one selected from the group consisting of, for example, formic acids, hydrazines, hypophosphite compounds, phosphite compounds, amine borane compounds, and hydroborane compounds.

Formic acids include, for example, formic acid and formates.

Hydrazines include, for example, hydrazine; hydrazine hydrate such as hydrazine monohydrate; hydrazine salts such as hydrazine carbonate, hydrazine sulfate, hydrazine neutral sulfate, and hydrazine hydrochloride; organic derivatives of hydrazines such as pyrazoles, triazoles, and hydrazides.

Hypophosphite compounds include, for example, hypophosphorous acid and hypophosphites.

Phosphite compounds include, for example, phosphoric acid and phosphites.

Amine borane compounds include, for example, dimethylamine borane (DMAB) and trimethylamine borane (TMAB).

Examples of hydroboron compounds are borohydride alkali metal salts such as sodium borohydride (SBH) and potassium borohydride (KBH).

Salts include, for example, alkali metal salts such as sodium and potassium; alkaline earth metal salts such as magnesium and calcium; ammonium salts, quaternary ammonium salts, and amine salts including primary to tertiary amines.

The above reducing agent can be used alone or in combination.

The concentration of the reducing agent in the electroless palladium plating solution (single concentration when used alone, or total concentration when two or more kinds are used together) varies depending on the type of the reducing agent used, however, the concentration is preferably adjusted to provide sufficient reduction action. Although a high concentration of the reducing agent is desirable considering the plating deposition rate, excessively high concentration of the reducing agent may decrease the stability of the plating solution.

The concentration of the reducing agent in the plating solution is preferably 0.1 g/L or more, more preferably 1.0 g/L or more, and preferably 100 g/L or less, more preferably 50 g/L or less.

### Complexing Agent

Known complexing agents used in electroless palladium plating solutions can be used in the present invention.

For examples, the complexing agent includes amines such as ethylenediamine and diethylenetriamine; aminopolycarboxylic acids such as ethylenediamine diacetic acid, ethylenediamine tetraacetic acid, diethylenetriamine pentaacetic acid, and their salts; amino acids such as glycine, alanine, iminodiacetic acid, nitrilotriacetic acid, L-glutamic acid, L-glutamic acid 2-acetic acid, L-aspartic acid, taurine, and their salts; aminotrimethylene phosphonic acid, 1-hydroxyethylidene-1,1-diphosphonic acid, ethylenediamine tetramethylene phosphonic acid, and their salts.

Salts include, for example, alkali metal salts such as sodium, and potassium; alkaline earth metal salts such as calcium; and ammonium salts.

The above complexing agent can be used alone or in combination.

The concentration of the complexing agent (the single concentration when used alone, or the total concentration when two or more are used together) is preferably 0.5 g/L or more, more preferably 5 g/L or more, and preferably 100 g/L or less, more preferably 50 g/L or less.

The electroless palladium plating solution may contain other known additives used for electroless palladium plating solutions as needed.

The additives include, for example, stabilizers, pH adjusters, and surfactants. Various known stabilizers, pH adjusters, and surfactants can be used for the electroless palladium plating solution and specific examples thereof are same examples described in various additives for the electroless nickel-germanium alloy plating solution, and the content of the additives for the electroless palladium plating solution is comparable to that of the electroless nickel-germanium alloy plating solution.

pH

The pH of the electroless palladium plating solution is preferably 2 or higher, more preferably 3 or higher, and preferably 9 or lower, more preferably 8 or lower.

### Temperature

The temperature during treatment of the electroless palladium plating solution is set for the same reason as the solution temperature of the electroless nickel-germanium alloy plating solution, and the temperature is preferably 30° C. or higher, more preferably 40° C. or higher, and preferably 90° C. or lower, more preferably 80° C. or lower.

### Electroless Gold Plating Treatment

The electroless gold plating film is formed on the surface of the electroless palladium plating film. The electroless gold plating film can be formed (laminated) on the surface of the electroless palladium plating film by immersing the object to be plated with the electroless palladium plating film in the electroless gold plating solution.

The immersion time is not limited, and the immersion time may be selected such as 2 to 60 minutes to form the desired electroless gold plating film with the desired thickness.

### Electroless Gold Plating Solution

Various known immersion gold plating solutions and reduction gold plating solutions can be used for the electroless gold plating treatment. A suitable example of an immersion gold plating solution is described below. Known immersion gold plating solutions and immersion gold plating methods used for forming ENEPIG can be adopted as the immersion plating solution and the plating method in the present invention.

The immersion gold plating solution is an aqueous solution containing a water-soluble gold compound and a complexing agent as essential components.

Known water-soluble gold salts can be used as the water-soluble gold compound, such as cyanide containing gold plating solution and cyanide free gold plating solution, preferably cyanide free gold plating solution.

The cyanide containing gold plating solution includes, for example, gold thiocyanate or gold thiocyanate salts such as potassium gold cyanide, sodium gold cyanide, and ammonium gold cyanide.

The cyanide free gold plating solution includes, for example, gold sulfite, gold thiosulfate, gold chloride, or their salts; and salts include alkali metal salts such as sodium, potassium, and lithium; alkaline earth metal salts such as calcium; and soluble salts such as ammonium salts.

These water-soluble gold compounds can be used alone or in combination.

The concentration of the water-soluble gold compound in the immersion gold plating solution (single concentration when used alone, or total concentration when two or more compounds are used together) is preferably high concentration considering the above effects of the immersion gold plating film. On the other hand, as the concentration of the water-soluble gold compound excessively increases, the stability of the plating solution may decrease.

The concentration of the water-soluble gold compound (the single concentration when used alone, or the total concentration when two or more are used together) is preferably 0.1 g/L or more, more preferably 0.5 g/L or more, and preferably 30 g/L or less, more preferably 10 g/L or less.

### Complexing Agent

Known complexing agents used in electroless gold plating solutions can be used in the present invention.

Examples of the complexing agent include amines such as ethylenediamine and diethylenetriamine; aminopolycarboxylic acids such as ethylenediamine diacetic acid, ethylenediaminetetraacetic acid, diethylenetriamine pentaacetic acid, and their salts; amino acids such as glycine, alanine, iminodiacetic acid, nitrilotriacetic acid, L-glutamic acid, L-aspartic acid, taurine, and their salts; alkyl sulfonic acids such as aminotrimethylene phosphonic acid, ethylenediamine tetramethylene phosphonic acid, methane sulfonic acid, ethane sulfonic acid, and their salts; alkanol sulfonic acids such as hydroxymethane sulfonic acid, hydroxyethane sulfonic acid, and their salts; aromatic sulfonic acids such as benzene sulfonic acid, p-phenol sulfonic acids, and their salts. Salts include, for example, alkali metal salts such as sodium, and potassium; alkaline earth metal salts such as calcium; and ammonium salts.

The above complexing agents can be used alone or in combination.

The concentration of the complexing agent (the single concentration when used alone, or the total concentration when two or more are used together) is preferably 0.5 g/L or more, more preferably 5 g/L or more, and preferably 100 g/L or less, more preferably 50 g/L or less.

The immersion gold plating solution may contain other known additives used for immersion gold plating solutions as needed.

The additives include, for example, stabilizers, pH adjusters, and surfactants. Various known stabilizers, pH adjusters, and surfactants can be used for immersion gold plating solutions and specific examples thereof are same examples described in various additives of the electroless nickel-germanium alloy plating solution, and the content of additives for the immersion gold plating solution is comparable to that of the electroless nickel-germanium alloy plating solution.

pH

The pH of the immersion gold plating solution is preferably 2 or higher, more preferably 3 or higher, and preferably 9 or less, more preferably 8 or less.

### Temperature

The temperature during treatment of the immersion gold plating solution bay be set for considering the deposition rate and the stability of the plating composition. The temperature is preferably 50° C. or higher, more preferably 60° C. or higher, and preferably 90° C. or lower, more preferably 80° C. or lower.

### Examples

Hereinafter, the present invention is described in more detail with reference to Examples. The present invention is not restricted by the Examples, may be carried out with appropriate modifications to the extent adaptable to the gist of the above and the following description. These variations are included in the technical scope of the present invention.

Solder bonding reliability was evaluated after applying plating process successively under the following conditions.

A substrate was prepared by cutting a copper clad laminate (MCL-E-67 manufactured by Hitachi Chemical) into 5 cm squares. Electroless Ni plating process and electroless Pd plating process were applied to the substrate in the order shown in Table 1 to laminate an electroless Ni plating film (film thickness: 6.0 μm) and an electroless Pd plating film (film thickness: 0.1 μm) shown in Table 1. Then, an immersion gold plating film (film thickness: 0.10 μm) was formed on the electroless Pd plating film by an immersion gold plating treatment. Water cleaning was performed between each process. The solder bonding reliability of each prepared sample was evaluated under the following conditions.

Ge content in the electroless Ni plating film (electroless Ni—Ge alloy plating film) was measured under the following conditions.

After the electroless Ni plating film was deposited on the copper clad laminate in the same manner as above, the Ni plating film was completely dissolved in nitric acid, and the nitric acid solution was examined by an ICP emission spectrometer.

TABLE 1

| Plating process | | | Temperature (° C.) | Time (min) |
|---|---|---|---|---|
| Cleaner treatment | C. Uyemura & Co. ACL-007 | | 50 | 5 |
| Hot water treatment | Hot ion exchanged water | | 50 | 1 |
| Soft etching | Persulfuric acid Na | 100 g/L | 25 | 1 |
| | Sulfuric acid | 20 g/L | | |
| Acid cleaning | Sulfuric acid | 50 g/L | room temp. | 1 |
| Pre-dip | Sulfuric acid | 15 g/L | room temp. | 1 |

| | | | |
|---|---|---|---|
| Activator | C. Uyemura & Co. MNK-4 | 30 | 2 |
| Electroless nickel plating | See Table 2, Table 3 | 80 | 30 |
| Electroless palladium plating | C. Uyemura & Co. TPD-30 | 50 | 10 |
| Electroless gold plating | C. Uyemura & Co. TWX-40 | 80 | 15 |

TABLE 2

| Plating bath composition | | Example | Example | Example | Example | Example | Example |
|---|---|---|---|---|---|---|---|
| Component | Unit | 1 | 2 | 3 | 4 | 5 | 6 |
| Nickel sulfate hexahydrate (as Ni) | g/L | 4.5 | 4.5 | 4.5 | 4.5 | 4.5 | 4.5 |
| Sodium hypophosphite | g/L | 35 | 35 | 35 | 35 | 35 | 35 |
| Citric acid | g/L | 30 | 30 | 30 | 30 | | |
| Succinic acid | g/L | | | | | 30 | |
| Malic acid | g/L | | | | | | 30 |
| Gluconic acid | g/L | | | | | | |
| Lead acetate (as Pb) | mg/L | 0.5 | 0.5 | 0.5 | 0.5 | 0.5 | 0.5 |
| Germanium oxide (as Ge) | g/L | 0.03 | 1 | 10 | 20 | 10 | 10 |
| pH | | 7 | 7 | 7 | 7 | 7 | 7 |
| Temperature | [° C.] | 80 | 80 | 80 | 80 | 80 | 80 |
| Ge content in the electroless | [wt %] | 0.018 | 1.4 | 9.7 | 23.6 | 3.2 | 4.8 |
| Ni-Ge alloy plating film | | | | | | | |
| Bonding reliability | evaluation | Excellent | Excellent | Excellent | Excellent | Excellent | Excellent |
| | Breakage | 90 | 100 | 100 | 95 | 100 | 100 |
| | rate(%) | | | | | | |

| Plating bath composition | | Example | Example | Example | Compvatative |
|---|---|---|---|---|---|
| Component | Unit | 7 | 8 | 9 | Example 1 |
| Nickel sulfate hexahydrate (as Ni) | g/L | 4.5 | 4.5 | 4.5 | 4.5 |
| Sodium hypophosphite | g/L | 35 | 35 | 35 | 35 |
| Citric acid | g/L | | 30 | 30 | 30 |
| Succinic acid | g/L | | | | |
| Malic acid | g/L | | | | |
| Gluconic acid | g/L | 30 | | | |
| Lead acetate (as Pb) | mg/L | 0.5 | 0.5 | 0.5 | 0.5 |
| Germanium oxide (as Ge) | g/L | 10 | 0.01 | 25 | 0 |
| pH | | 7 | 7 | 7 | 7 |
| Temperature | [° C.] | 80 | 80 | 80 | 80 |
| Ge content in the electroless | [wt %] | 2.7 | 0.007 | 27.2 | 0 |
| Ni-Ge alloy plating film | | | | | |
| Bonding reliability | evaluation | Excellent | Acceptable | Acceptable | Poor |
| | Breakage | 100 | 80 | 75 | 65 |
| | rate(%) | | | | |

TABLE 3

| Plating bath composition | | | Comparative | Comparative | Comparative |
|---|---|---|---|---|---|
| Component | Unit | Example 10 | Example 2 | Example 3 | Example 4 |
| Nickel sulfate hexahydrate (as Ni) | g/L | 4.5 | 4.5 | 4.5 | 4.5 |
| Sodium hypophosphite | g/L | 35 | 35 | 35 | 35 |
| Citric acid | g/L | 30 | 30 | 30 | 30 |
| Lead acetate (as Pb) | mg/L | 0.5 | 0.5 | 0.5 | 0.5 |
| Germanium oxide (as Ge) | g/L | 5 | | | |
| Iron sulfate (as Fe) | g/L | | 5 | | |
| Copper sulfate (as Cu) | g/L | | | 5 | |
| Stannous chloride (as Sn) | g/L | | | | 5 |
| pH | | 7 | 7 | 7 | 7 |
| Temperature | [° C.] | 80 | 80 | 80 | 80 |
| Ge content in the electroless Ni—Ge | [wt %] | 5.4 | | | |
| alloy plating film | | | | | |
| Bonding reliability | evaluation | Excellent | Poor | Poor | Poor |
| | Breakage rate(%) | 100 | 60 | 30 | 10 |

### Evaluation of Solder Bonding Reliability

Bonding reliability was evaluated by the ball-pull test with 20 points per condition. The film was formed on a substrate with a solder resist (SR) aperture of 0.5 mm in diameter. A 0.6 mm solder ball (Sn-3 Ag-0.5 Cu, SAC305) was mounted in the SR aperture using a reflow device (ANTOM UNI-6116α). The ball was mounted under heat treatment conditions of 260° C. (TOP temperature). The ball pull test was conducted using a bond tester (Bond tester SERIES 4000 manufactured by Dage) to evaluate the breaking mode. Solder breakage was set as the OK mode and plating film breakage was set as the NG mode. Solder breakage rate of 85% or more in the OK mode was evaluated as “excellent”, solder breakage rate of between 70% and 85% was evaluated as “acceptable”, and solder breakage rate of less than 70% was evaluated as “poor”. The evaluation conditions are summarized below.

### (Measurement Conditions)

Measuring method: Ball-pull test
Solder balls: SAC305 (0.6 mm diameter) manufactured by Senju Metal Industry Co.
Reflow device: UNI-6116α manufactured by ANTOM
Reflow condition: Top 260° C.
Reflow environment: Air
Number of reflow: 7 times
Flux: 529D-1 (RMA type) manufactured by Senju Metal Co.
Test speed: 1000 μm/sec.
Aging after solder mounting: 1 hour
Evaluation substrate: BGA substrate (Ball Grid Array: Manufactured by C. Uyemura & Co. 5 cm×5 cm, 0.5 mm diameter)

The results of the experiment can be discussed as follows.

Examples 1-10 were inventive examples of electroless Ni plating film containing Ge (electroless Ni—Ge alloy plating film). All of these showed excellent bonding reliability.

Example 8 was an example in which the germanium content was below the suitable range (0.01 mass %), and the bonding reliability was inferior compared to other inventive examples.

Example 9 was an example with a higher germanium content than the other examples, and bonding reliability thereof was inferior to the other inventive examples.

Comparative Example 1 was a comparative example in which the electroless Ni plating film did not contain Ge. Comparative Example 1 had poor bonding reliability.

Comparative Examples 2-4 were comparative examples in which the electroless Ni plating films did not contain Ge. Comparative Example 2 was an electroless Ni—Fe plating film, Comparative Example 3 was an electroless Ni—Cu plating film, and Comparative Example 4 was an electroless Ni—Sn plating film. Comparative Examples 2-4 had poor bonding reliability.

From the above results, excellent bonding reliability is the effect unique to the electroless Ni plating film containing Ge as an alloy component (electroless Ni—Ge alloy plating film).

### REFERENCE SINGS LIST

1 Substrate
2 Conductor
3 Electroless nickel-germanium alloy plating film
4 Electroless palladium plating film
5 Electroless gold plating film

1. A multilayer plating film comprising:
an electroless nickel-germanium alloy plating film;
an electroless palladium plating film; and
an electroless gold plating film in this order.

2. The multilayer plating film according claim 1, wherein a content of germanium in the electroless nickel-germanium alloy plating film is 0.01 to 25 mass %.

3. A wiring substrate comprising:
a conductor surface of the wiring substrate is laminated by the electroless nickel-germanium alloy plating film, the electroless palladium plating film, and the electroless gold plating film according to claim 1 in this order.
